(19) United States
(12) Patent Application Publication
(10) Pub. No.: US 2012/0217579 A1
(43) Pub. Date: Aug. 30, 2012

(54) High voltage device and manufacturing method thereof

(75) Inventors: Tsung-Yi Huang, (US); Ying-Shiou Lin, (US)

(73) Assignee: Richtek Technology Corporation, R.O.C.

(21) Appl. No.: 13/136,703

(22) Filed: Aug. 8, 2011

(30) Foreign Application Priority Data
Feb. 25, 2011 (TW) 100106486

(51) Int. Cl. H01L 29/78; H01L 21/336

(52) U.S. Cl. 257/335; 438/286; 257/E29.256; 257/E21.417

(57) ABSTRACT

The present invention discloses a high voltage device and a manufacturing method thereof. The high voltage device includes: a substrate, having a P (or N) type well and an isolation structure for defining a device region; a drift region, located in the device region, having a first region and a second region wherein the first region is an N (or P) type region, and the second region is a P (or N) type region or an N (or P) type region with different dopant concentration from the first region, and from top view, the first region and the second region include sub-regions distributed in the drift region; an N (or P) type source and drain; and a gate on a surface of the substrate, between the source and drain in the device region.

### CROSS REFERENCE

The present invention claims priority to TW 100106486, filed on Feb. 25, 2011.

### BACKGROUND OF THE INVENTION

1. Field of Invention

The present invention relates to a high voltage device and a manufacturing method thereof, in particular to such device with an enhanced breakdown voltage and a method for manufacturing the device.

2. Description of Related Art

FIGS. 1A and 1B respectively show a cross-section view and a 3D (3-dimensional) view of a prior art double diffused drain metal oxide semiconductor (DDDMOS) device which is manufactured by the following steps: as shown in FIGS. 1A and 1B, forming an isolation structure 12 and a P-type well 11 in a substrate 1 to define a device region 100, wherein the isolation structure 12 is, for example, a shallow trench isolation (STI) structure or a local oxidation of silicon (LOCOS) structure; and forming a gate 13, a drift region 14, a drain 15 and a source 16 in the first device region 100. The p-type well 11 can be the substrate 1 itself; the drift region 14, the drain 15 and the source 16 are formed by a lithography process and an ion implantation process, wherein the lithography process defines the implantation regions, and the ion implantation process implants N-type impurities to the drift region 14, the drain 15 and the source 16. The drain 15 and the source 16 are at different sides of the gate 13 respectively, and the drift region 14 partially interfaces with the bottom surface of the gate 13 at a side of the gate 13 closer to the drain 15 than the source 16. The DDDMOS device is a high voltage device designed for applications requiring higher operation voltages. However, if it is required for the DDDMOS device to be integrated with a low voltage device in one substrate, the high voltage device and the low voltage device should adopt the same manufacturing process steps with the same ion-implantation parameters, and thus the flexibility of the ion-implantation parameters for the DDDMOS device is limited; as a result, the DDDMOS device has a lower breakdown voltage and a limited application range. To increase the breakdown voltage of the DDDMOS device, additional manufacturing process steps are required, that is, other lithography process and ion implantation process are required in order to provide different ion-implantation parameters, but this increases the cost.

FIGS. 2A and 2B respectively show a cross-section view and a 3D view of a prior art lateral diffused metal oxide semiconductor (LDMOS) device. Compared with the device shown in FIGS. 1A and 1B, the LDMOS device shown in FIGS. 2A and 2B further includes a body region 17 and a body electrode 18, and the gate 13 is partially above the isolation region 12. Likely, if it is required for the LDMOS device to be integrated with the low voltage device in one substrate, the LDMOS voltage device and the low voltage device should preferably adopt the same manufacturing process steps; therefore, the LDMOS device will have a lower breakdown voltage and thus a limited application range. In order to increase the breakdown voltage of the LDMOS device, additional manufacturing process steps with different ion-implantation parameters are required, and this increases the cost.

In view of above, to overcome the drawbacks in the prior art, the present invention proposes a high voltage device and a manufacturing method thereof which provide a higher breakdown voltage and a broader application range for the high voltage device, in which additional manufacturing process steps are not required such that the high voltage device and the low voltage device can be manufactured by common manufacturing process steps.

### SUMMARY OF THE INVENTION

The objectives of the present invention are to provide a high voltage device and its manufacturing method.

To achieve the foregoing objectives, the present invention provides a high voltage device, comprising: a substrate having a first conductive type well and an isolation structure for defining a device region; a drift region located in the device region, the drift region having a first region and a second region, the first region having a second conductive type, and the second region having a first conductive type region or having the second conductive type region but with different dopant concentration from the first region, wherein from top view, the first region includes one or more first sub-regions distributed in the drift region and the second region includes one or more second sub-regions distributed in the drift region; a second conductive type source and a second conductive type drain in the device region; and a gate located on a surface of the substrate, between the source and drain in the device region.

In one embodiment of the high voltage device, the first region may be formed by doping second conductive type impurities in an area within the drift region, and the second region may be formed by thermal diffusion of a portion of the second conductive type impurities doped in the first region.

In one embodiment of the high voltage device, the first region may include multiple connected or unconnected first sub-regions, and the second region includes multiple connected or unconnected second sub-regions.

In another perspective of the present invention, it provides a method for manufacturing a high voltage device, comprising: providing a substrate, and forming a first conductive type well and an isolation structure in the substrate for defining a device region; forming a drift region located in the device region, the drift region having a first region and a second region, the first region having a second conductive type, and the second region having a first conductive type region or having the second conductive type region but with different dopant concentration from the first region, wherein from top view, the first region includes one or more first sub-regions distributed in the drift region and the second region includes one or more second sub-regions distributed in the drift region; forming a second conductive type source and a second conductive type drain in the device region; and forming a gate on a surface of the substrate, between the source and drain in the device region.

The objectives, technical details, features, and effects of the present invention will be better understood with regard to the detailed description of the embodiments below, with reference to the drawings.

### BRIEF DESCRIPTION OF THE DRAWINGS

FIG. 1A shows, by cross-section view, a prior art DDDMOS device.

FIG. 1B shows, by 3D view, a prior art DDDMOS device.

FIG. 2A shows, by cross-section view, a prior art LDMOS device.

FIG. 2B shows, by 3D view, a prior art LDMOS device.

FIGS. 3A-3D show a first embodiment according to the present invention.

FIGS. 4A-4B show a layout arrangement of alternating first region and second region in the drift region in one embodiment according to the present invention.

FIGS. 5A-5D show another embodiment according to the present invention.

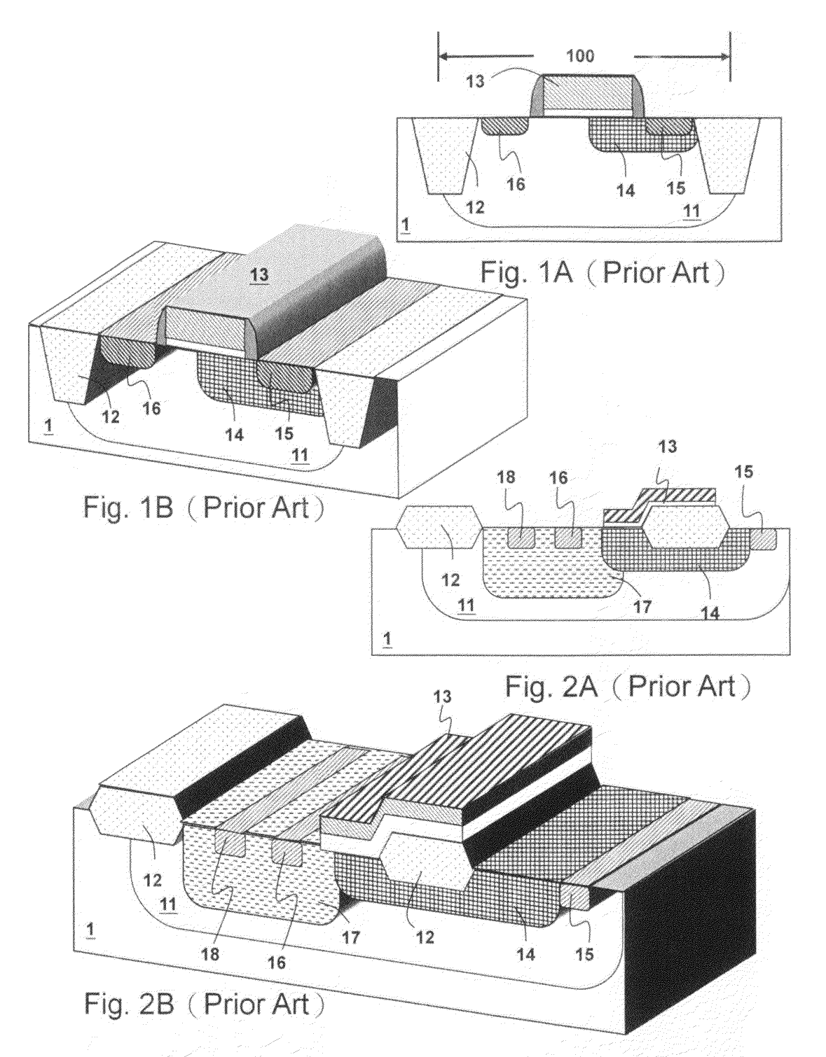

### DESCRIPTION OF THE PREFERRED EMBODIMENTS

The drawings as referred to throughout the description of the present invention are for illustration only, to show the interrelations between the regions and the process steps, but not drawn according to actual scale.

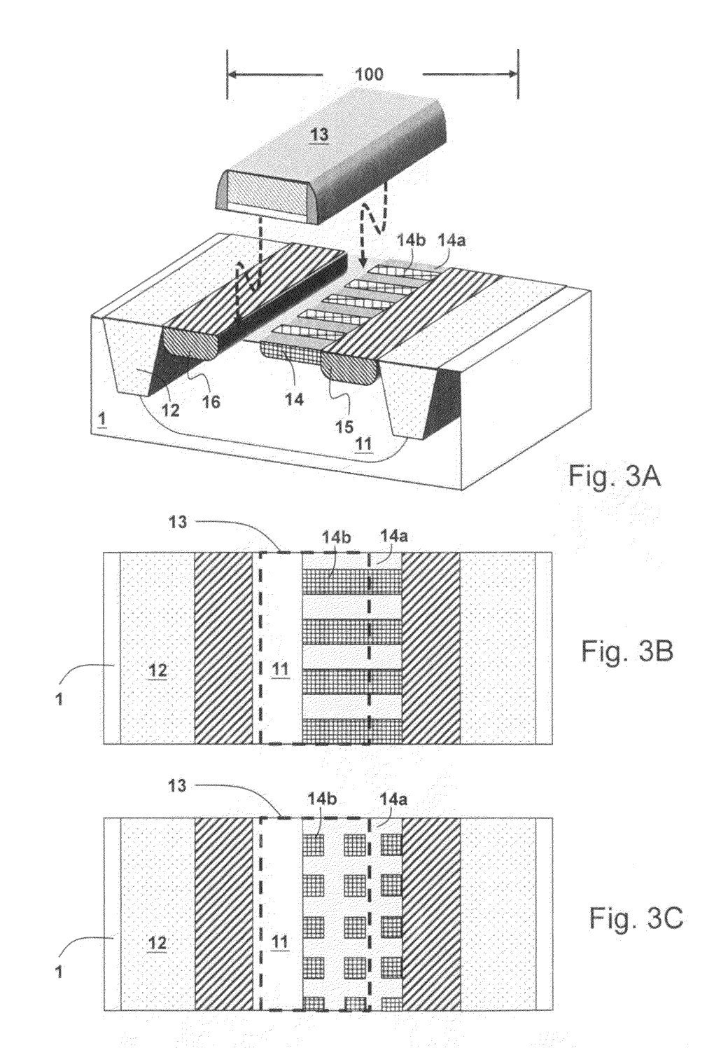

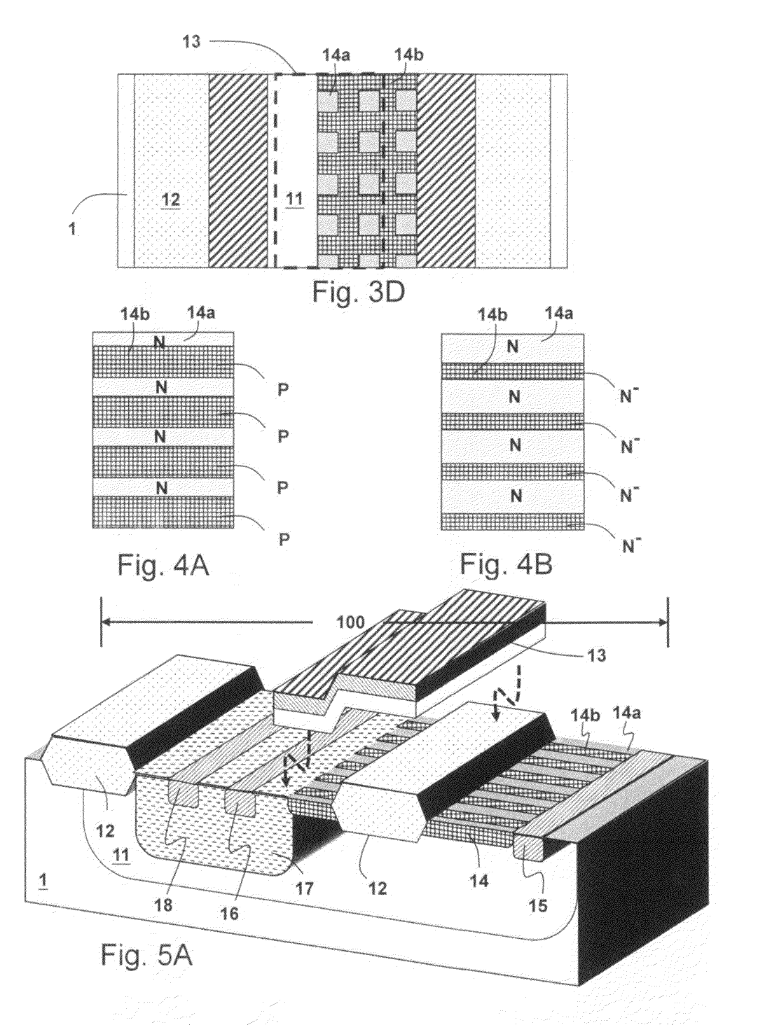

Please refer to FIGS. 3A-3D for a first embodiment according to the present invention, wherein FIG. 3A shows, by 3D view, a DDDMOS device of the present invention. It should be explained that in some of the figures the gate 13 is shown to be separated from the substrate 1 for purpose of better illustrating the feature of the present invention; the gate 13 and the substrate 1 are in physical contact with each other in practical case. As shown in FIG. 3A, a substrate 1 is provided, in which is formed a well 11 and an isolation structure 12 to define the device region 100, wherein the well 11 is, for example but not limited to, a P-type well, and the isolation structure 12 is, for example, an STI or a LOCOS structure. A gate 13, drift region 14, drain 15 and source 16 are formed in the device region 100, wherein the source 16 and drain 15 are, for example but not limited to, N-type regions. Different from the prior art, the drift region 14 includes a first region 14a and a second region 14b which are in alternating arrangement, wherein the first region 14a is, for example but not limited to, an N-type region, and the second region 14b is, for example but not limited to, a P-type region or another N-type region but with different dopant concentration from the first region 14a; and if the first regions 14a is a P-type region, the second region 14b can be an N-type region or another P-type region with different dopant concentration from the first region 14a. This arrangement has the following advantages: First, in device characteristics, the present invention enhances the breakdown voltage of the DDDMOS device. Second, in manufacturing process, if the DDDMOS device is manufactured in a wafer including other low voltage devices, the drift region 14 can be formed together with lightly doped drains (LDD) of other low voltage devices by the same mask and process steps so that no additional mask or process step is required. Therefore, the DDDMOS device in the present invention can be manufactured by a lower cost than the prior art.

Please refer to FIG. 3B for a top view of this embodiment. As shown in FIG. 3B, the first region 14a and the second region 14b are in alternating arrangement. In one embodiment, the first region 14a and the second region 14b may be formed in a way as the following: The first region 14a is defined by a mask and processes for the low voltage device, and is doped with N-type impurities; the second region 14b is not implanted with any impurities. After later thermal process steps, a portion of the N-type impurities in the first region 14a diffuse to the second region 14b, so the second region 14b becomes a light P-type region or a light N-type region. Referring to FIGS. 4A and 4B, it should be explained that the conductive type and impurity concentration of the second region 14b depend not only on the N-type impurity concentration of the first region 14a and the thermal processing steps, but also depend on the shape, size and arrangement of the first region 14a and the second region 14b. In FIG. 4A, the first region 14a is narrower and the second region 14b is wider, so the second region 14b may still be P-type; in FIG. 4B, the first region 14a is wider and the second region 14b is narrower, so the second region 14b may become N-type.

The arrangement of the first region 14a and the second region 14b is not limited to what shown in FIGS. 3B, 4A and 4B, but can be arranged otherwise, such as what shown in FIGS. 3C and 3D; in fact, the first region 14a and the second region 14b can be arranged regularly or irregularly in any form. In FIGS. 3B, 4A and 4B, the first region 14a includes multiple unconnected sub-regions, and the second region 14b includes multiple unconnected sub-regions. In FIG. 3C, the first region 14a includes multiple connected sub-regions, and the second region 14b includes multiple unconnected sub-regions. In FIG. 3D, the first region 14a includes multiple unconnected sub-regions, and the second region 14b includes multiple connected sub-regions. In summary, the first region 14a may include multiple connected or unconnected first sub-regions, and the second region 14b may include multiple connected or unconnected second sub-regions. The key is for the arrangement to achieve the following effect: when the drift region 14 is applied with a voltage exceeding a predetermined value, a junction between the first region 14a and the second region 14b preferably becomes a depletion region which makes a surface of the drift region 14 to be substantially depleted. Thus, the present invention can provide a higher breakdown voltage than the prior art.

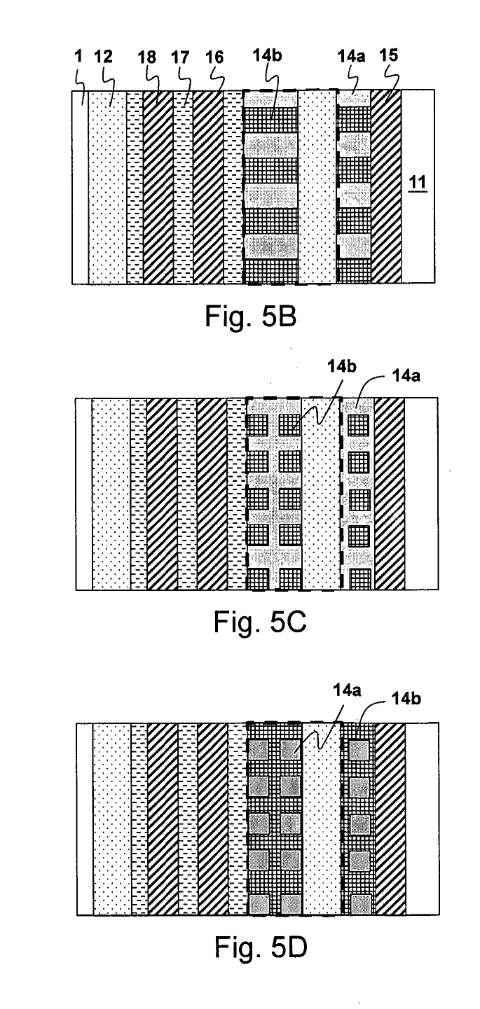

Please refer to FIGS. 5A-5D for another embodiment according to the present invention, wherein FIG. 5A shows, by 3D view, a LDMOS device of the present invention. Likely, in some of the figures the gate 13 is shown to be separated from the substrate 1 for purpose of better illustrating the feature of the present invention, but the gate 13 and the substrate 1 are in physical contact with each other in practical case. As shown in FIG. 5A, a substrate 1 is provided, in which is formed a well 11 and an isolation structure 12 to define the device region 100, wherein the well 11 is, for example but not limited to, a P-type well, and the isolation structure 12 is, for example, an STI or a LOCOS structure. A gate 13, drift region 14, drain 15, source 16, body region 17 and body electrode 18 are formed in the device region 100, wherein the source 16 and drain 15 are, for example but not limited to, N-type regions, and the body region 17 and the body electrode 18 are, for example but not limited to, P-type regions. Different from the prior art, the drift region 14 includes a first region 14a and a second region 14b which are in alternating arrangement, wherein the first region 14a is, for example but not limited to, an N-type region, and the second region 14b is, for example but not limited to, a P-type region or another N-type region with different dopant concentration from the first region 14a; and when the first regions 14a is a P-type region, the second region 14b can be an N-type region or is another P-type region with different dopant concentration from the first region 14a. If the LDMOS device is manufactured in a wafer including other low voltage devices, the drift region 14 can be formed together with LDDs of other low voltage devices by the same mask and process steps so that no additional mask or process step is required. Therefore, the LDMOS device in the present invention can be manufactured by a lower cost than the prior art.

Please refer to FIG. 5B for a top view of this embodiment. As shown in FIG. 5B, the first region 14a and the second region 14b are in alternating arrangement. In one embodiment, the first region 14a and the second region 14b may be formed in a way as the following: The first region 14a is defined by mask and processes for the low voltage device, and is doped with N-type impurities; the second region 14b is not implanted with any impurities. After later thermal process steps, a portion of the N-type impurities of the first region 14a diffuse to the second region 14b, so the second region 14b becomes a light P-type region or a light N-type region. The arrangement of the first region 14a and the second region 14b is not limited to what shown in FIGS. 5B, 4A and 4B, but can be arranged otherwise, such as what shown in FIGS. 5C and 5D; in fact, the first region 14a and the second region 14b can be arranged regularly or irregularly in any form.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other manufacturing process steps or structures which do not affect the characteristics of the devices, such as a deep-well region, etc., can be added. As another example, the lithography process is not limited to photolithography; it can be electron beam lithography, X-ray lithography or other methods. As yet another example, if the DDDMOS or LDMOS device of the present invention is manufactured in a wafer including other low voltage devices, the drift region 14 not only can be formed together with LDDs of other low voltage devices by the same mask and process steps, but also can be formed by other mask and process steps. Thus, the present invention should cover all such and other modifications and variations, which should be interpreted to fall within the scope of the following claims and their equivalents.

What is claimed is:

1. A high voltage device, comprising:
a substrate having a first conductive type well and an isolation structure for defining a device region;
adrift region located in the device region, the drift region having a first region and a second region, the first region having a second conductive type, and the second region having a first conductive type region or having the second conductive type region but with different dopant concentration from the first region, wherein from top view, the first region includes one or more first sub-regions distributed in the drift region and the second region includes one or more second sub-regions distributed in the drift region;
a second conductive type source and a second conductive type drain in the device region; and
a gate located on a surface of the substrate, between the source and drain in the device region.

2. The high voltage device of claim 1, wherein when the drift region is applied with a voltage exceeding a predetermined value, a junction between the first region and the second region becomes a depletion region which makes a surface of the drift region substantially depleted.

3. The high voltage device of claim 1, wherein the first region is formed by doping second conductive type impurities in an area within the drift region, and the second region is formed by thermal diffusion of a portion of the second conductive type impurities doped in the first region.

4. The high voltage device of claim 1, wherein the first region includes multiple connected or unconnected first sub-regions.

5. The high voltage device of claim 1, wherein the second region includes multiple connected or unconnected second sub-regions.

6. A method for manufacturing a high voltage device, comprising:
providing a substrate, and forming a first conductive type well and an isolation structure in the substrate for defining a device region;
forming a drift region located in the device region, the drift region having a first region and a second region, the first region having a second conductive type, and the second region having a first conductive type region or having the second conductive type region but with different dopant concentration from the first region, wherein from top view, the first region includes one or more first sub-regions distributed in the drift region and the second region includes one or more second sub-regions distributed in the drift region;
forming a second conductive type source and a second conductive type drain in the device region; and
forming a gate on a surface of the substrate, between the source and drain in the device region.

7. The method of claim 6, wherein when the drift region is applied with a voltage exceeding a predetermined value, a junction between the first region and the second region becomes a depletion region which makes a surface of the drift region substantially depleted.

8. The method of claim 6, wherein the step of forming a drift region having a first region and a second region includes: doping second conductive type impurities in an area within the drift region to form the first region; and diffusing a portion of the second conductive type impurities doped in the first region to form the second region.

9. The method of claim 6, wherein the first region includes multiple connected or unconnected first sub-regions.

10. The method of claim 6, wherein the second region includes multiple connected or unconnected second sub-regions.
